(19) United States
(12) Patent Application Publication
(10) Pub. No.: US 2023/0402558 A1
(43) Pub. Date: Dec. 14, 2023

(54) HOT CARRIER SOLAR CELL AND TANDEM SOLAR CELL

(71) Applicant: National Taiwan University, Taipei (TW)

(72) Inventors: Ching-Fuh Lin, Taipei (TW); Chung-Han Chang, Taipei (TW)

(21) Appl. No.: 17/961,465

(22) Filed: Oct. 6, 2022

(30) Foreign Application Priority Data
Jun. 8, 2022 (TW) 111121261

(51) Int. Cl. H01L 31/055; H01L 31/0224

(52) U.S. Cl. CPC H01L 31/055; H01L 31/0224

(57) ABSTRACT

A hot carrier solar cell capable of absorbing sunlight with wavelengths greater than 1100 nm includes a light-absorbing layer in contact with a semiconductor layer, and a first and a second electrode in contact with the light-absorbing layer and the semiconductor layer, respectively. The hot carrier solar cell can be produced in a lower cost using a simple process. In addition, a tandem solar cell having the above-mentioned hot carrier solar cell is also disclosed to improve the efficiency of the tandem solar cell.

### CROSS-REFERENCE TO RELATED APPLICATIONS

The entire contents of Taiwan Patent Application No. 111121261, filed on Jun. 8, 2022, from which this application claims priority, are expressly incorporated herein by reference.

### BACKGROUND OF THE INVENTION

### 1. Field of the Invention

The present invention relates to a hot carrier solar cell and a tandem solar cell having the hot carrier solar cell.

### 2. Description of Related Art

Solar energy is a clean, safe, and renewable energy source. The cost of solar power has dropped sharply in recent years, showing its potential to be widely used in the future.

Compared with thermal power generation, the solar power generation has lower operation but higher construction cost. In order to reduce costs, improving the conversion efficiency of solar panels to increase the power generated per unit area is the most important problem to be overcome in the development of solar power generation.

Table 1 lists the main types of solar cells on the market and their conversion efficiencies. Common solar photovoltaic cells include commercialized silicon-based, thin-film, and III-V compound semiconductor solar cells, as well as future commercialized organic and perovskite solar cells. Constrained by large-scale commercialization technology, commercially available products, even the most mature silicon cells, are still unable to break through the conversion efficiency of 25% under the same cost conditions.

TABLE 1

| | Material of | conversion |
|---|---|---|
| | solar cell | efficiency |
| commercialized | single crystalline Si | 18-23% |
| | Polycrystalline Si | 17-20% |
| | thin-film | 13-20% |
| | III-V compound | 43.5% |
| future | perovskite | 23.3% |
| commercialized | organic | 5-15% |

In order to improve the power generation efficiency of solar photovoltaic systems, many research groups are working on developing tandem solar cells. With the same effective area, the higher the photoelectric conversion efficiency of solar cells, the more obvious the economic advantage. The tandem solar cells are based on a double junction solar cell with a theoretical efficiency of up to 47%. As to multi-junction solar cells, for example, the National Renewable Energy Laboratory (NREL) disclosed a six-junction solar cell with 47.1% conversion efficiency, and the German team (Fraunhofer ISE) disclosed a three-junction solar cell with 35.9% conversion efficiency. Both the two cells are made of III-V semiconductors. Although multi-junction solar cells have high efficiency, their epitaxial process is complicated, and the manufacturing cost is high.

The radiant energy of the entire AM 1.5 sunlight spectrum is mainly concentrated in the region of wavelength 0.15-4 μm, of which ultraviolet regime accounts for 5%, visible regime 52%, and infrared regime 43%. The conversion efficiency of existing solar cells mainly comes from the contribution of visible light band (400-800 nm). Only photons with energy higher than the forbidden band width of the semiconductor can be absorbed. This determines the minimum photon energy, i.e., the maximum wavelength, of photons that can be absorbed by the semiconductor. The forbidden band width of general materials is between 1 and 1.7 eV, and the maximum wavelength of photons that can be absorbed by the material is about 730-1240 nm, i.e., the visible light to near-infrared light range. At present, the absorption spectrum of commercially available Si solar cells are mostly between 300-1100 nm, accounting for 80.43% of the entire AM 1.5 solar spectrum radiant energy, while the remaining solar energy, that is, the near-infrared light to the mid-infrared light above 1100 nm, accounts for 19.57% and cannot be used effectively.

In order to effectively utilize infrared light with wavelengths above 1100 nm, several materials with an energy gap lower than 1.1 eV are applied to solar cells as light-absorption layers. In the past, Group III-V and Group II-VI compounds, such as GaSb, InAs, CIS or InGaAsSb compounds, etc., were mostly used. Although these materials have matured epitaxial technology and have been used in high-efficiency tandem cells, they have several disadvantages, such as the high material costs due to some rare sources on earth, and difficulties in the epitaxy.

### SUMMARY OF THE INVENTION

The present invention relates to a hot carrier solar cell and a tandem solar cell having the hot carrier solar cell.

In some embodiments, a hot carrier solar cell includes a semiconductor layer, a light-absorbing layer, a first electrode, and a second electrode. A lower surface of the light-absorbing layer is in contact with an upper surface of the semiconductor layer. The first electrode is in contact with an upper surface of the light-absorbing layer. The second electrode is in contact with a lower surface of the semiconductor layer. Carriers in the light-absorbing layer or the semiconductor layer are excited by the incident photons to form hot carriers crossing the interface between the light-absorbing layer and the semiconductor layer and thus generates a photocurrent.

In some embodiments, the energy gap of the light-absorbing layer is less than or equal to 0.5 eV. In some embodiments, a Schottky energy barrier between 0.2-1.1 eV is formed at the interface of the light-absorbing layer and the semiconductor layer.

In some embodiments, a tandem solar cell includes a first unit and a second unit. The first unit includes a hot carrier sub-solar cell for converting incident light with wavelengths greater than 1100 nm into electricity. The second unit includes one or more perovskite sub-solar cells for converting incident light with wavelengths below 1100 nm into electricity.

In some embodiments, the conversion efficiency of the hot carrier sub-solar cell is greater than 3.3% for incident light with wavelengths greater than 1100 nm and an incident intensity of 13.85 mW/cm².

### BRIEF DESCRIPTION OF THE DRAWINGS

FIG. 1 shows a solar cell 1 in accordance with an embodiment of the present invention.

FIG. 2 shows an energy band diagram of a solar cell in accordance with some embodiments of the present invention.

FIG. 3 shows an energy band diagram of a solar cell in accordance with some embodiments of the present invention.

FIG. 4 is a schematic side view showing a solar cell in accordance with another embodiment of the present invention.

FIG. 5 is a scanning electron microscope photograph showing the deposited silver thin films on silicon substrate at different evaporation rates.

FIG. 6 shows a measuring arrangement for measuring a solar cell in accordance with an embodiment of the present invention.

FIG. 7A and FIG. 7B show the current-voltage characteristic curves of the presented solar cell and the comparative sample, using the measuring arrangement of FIG. 6 with and without the filter, respectively.

FIG. 8 is a schematic side view showing a solar cell in accordance with another embodiment of the present invention.

FIG. 9A is a schematic diagram showing a solar cell in accordance with another embodiment of the present invention.

FIG. 9B shows an energy band diagram of the solar cell of FIG. 9A.

FIG. 9C shows another energy band diagram of the solar cell of FIG. 9A.

FIG. 10A is a schematic diagram showing a solar cell in accordance with another embodiment of the present invention.

FIG. 10B shows an energy band diagram of the solar cell of FIG. 10A.

FIG. 10C shows another energy band diagram of the solar cell of FIG. 10A.

FIG. 11 is a schematic diagram illustrating a tandem solar cell in accordance with an embodiment of the present invention.

### DETAILED DESCRIPTION OF THE PREFERRED EMBODIMENT

Reference will now be made in detail to those specific embodiments of the invention. Examples of these embodiments are illustrated in accompanying drawings. While the invention will be described in conjunction with these specific embodiments, it will be understood that it is not intended to limit the invention to these embodiments. On the contrary, it is intended to cover alternatives, modifications, and equivalents as may be included within the spirit and scope of the invention as defined by the appended claims. In the following description, numerous specific details are set forth in order to provide a thorough understanding of the present invention. The present invention may be practiced without some or all of these specific details. In other instances, well-known process operations and components are not described in detail in order not to unnecessarily obscure the present invention.

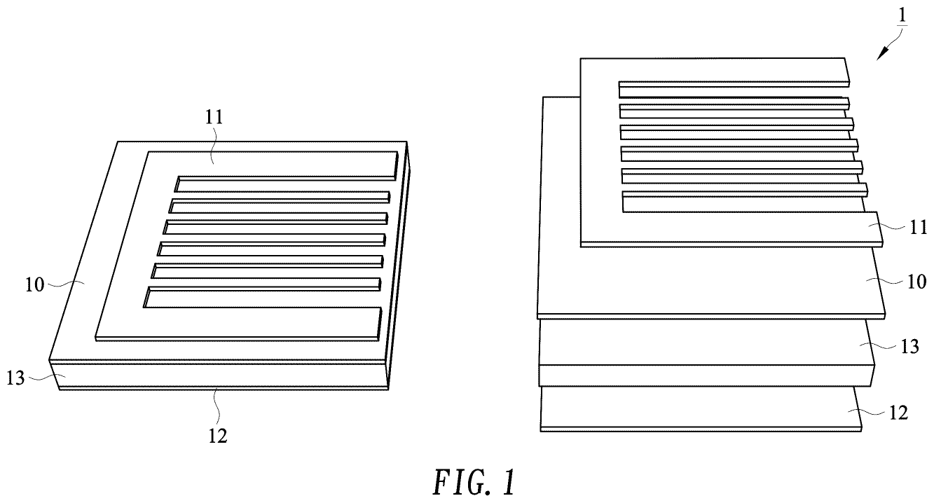

FIG. 1 shows a solar cell 1 in accordance with an embodiment of the present invention. Referring to FIG. 1, the solar cell 1 includes a light-absorbing layer 10, a semiconductor 13, a first electrode 11, and a second electrode 12. A lower surface of the light-absorbing layer 10 is in contact with an upper surface of the semiconductor 13. The first electrode 11 is in contact with an upper surface of the light-absorbing layer 10. The second electrode 12 is in contact with the lower surface of the semiconductor 13. The carriers in the light-absorbing layer 10 or the semiconductor 13 are excited by the incident photons to form hot carriers crossing the interface between the light-absorbing layer 10 and the semiconductor 13 and thus generating a photocurrent.

In some embodiments, the semiconductor 13 is preferably silicon, and the bandgap of the light-absorbing layer 10 is less than or equal to 0.5 eV. In some embodiments, the light-absorbing layer 10 is made of a semiconductor, such as but not limited to, indium arsenide (InAs) or indium antimonide (InSb). In some embodiments, the light-absorbing layer 10 is made of metal, such as but not limited to, gold, silver, copper, chromium, nickel. In general, the thickness of the light-absorbing layer 10 is less than or equal to 100 nm. In some embodiments, the thickness of the light-absorbing layer 10 is less than or equal to 50 nm.

Preferably, the thickness of the light-absorbing layer 10 is less than or equal to 30 nm.

In some embodiments, a metal-bonding layer (not shown) is further provided between the first electrode 11 and the light-absorbing layer 10. In some embodiments, there is also a metal-bonding layer (not shown) between the second electrode 12 and the semiconductor 13. The metal-bonding layer may be made of, such as but not limited to, titanium.

The following example illustrates the fabrication of the solar cell 1.

First of all, a semiconductor substrate 13, such as a silicon substrate, is sliced into a size of 2.5 cm×2.5 cm. Next, the sliced silicon substrate is immersed in a buffered oxide etchant to etch the silicon dioxide naturally formed on the surface of the silicon substrate.

The presence or absence of a residual oxide layer can be confirmed through the hydrophobicity of the surface of the silicon substrate.

Next, via thermal evaporation, the surface of the silicon substrate is deposited with a silver film with a thickness of 10 nm as the light-absorbing layer 10. Next, via thermal evaporation, a finger-shaped silver film with a thickness of 100 nm is deposited on the surface of the light-absorbing layer 10 as the first electrode 11, and an aluminum film is deposited on the bottom surface of the silicon substrate as the second electrode 12. The finger-shaped first electrode 11 is favorable for light transmission, and it can also be rectangular or other shapes. In the exemplary embodiment of FIG. 1, the incident light enters from the top of the solar cell. In some embodiments, the incident light enters from the bottom of the solar cell, in which case the second electrode 12 may be finger-shaped, and the first electrode 11 may be rectangular.

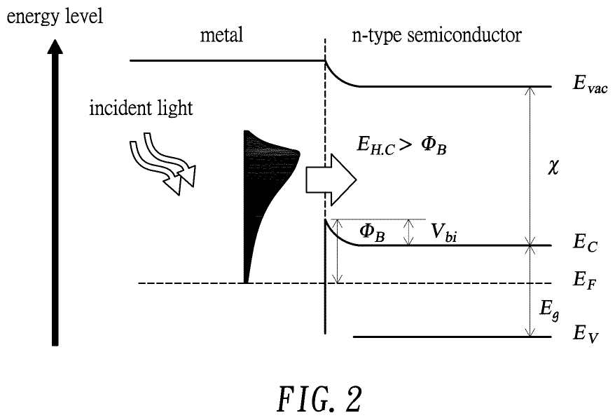

FIG. 2 shows an energy band diagram of a solar cell in accordance with some embodiments of the present invention. In the exemplary embodiment, the solar cell may have a structure described in FIG. 1, wherein the light-absorbing layer is made of a metal, the semiconductor is an n-type semiconductor, and the main carriers are electrons. The metal and semiconductor each have its own energy band, Fermi level, and energy gap before contacting with each other. The energy gap (Eg) of the semiconductor is the energy difference between the conduction band (Ec) and the valence band (Ev). The work function is defined as the energy difference from the Fermi level to the vacuum level (Evac). The work function (qϕm) of metal is greater than that of semiconductor (qϕs). As shown in FIG. 2, a thermal equilibrium is reached after metal and semiconductor contact with each other, and in an ideal state, the Fermi levels of metal and semiconductor are equal. If the main carrier electrons in the n-type semiconductor are needed to flow to the metal, the built-in electric field V_{bi} at the junction must be overcome. If the main carrier electrons in the metal are needed to flow to the semiconductor, the barrier height ϕb at the junction must be overcome. The barrier height ϕb is the energy difference between the Fermi level and the conduction band of the semiconductor at band edge with majority carriers.

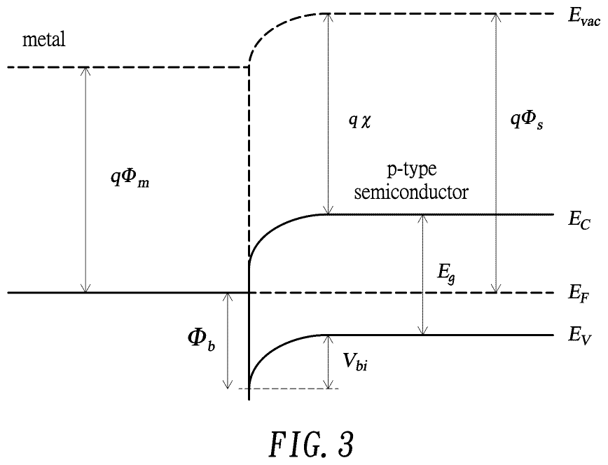

FIG. 3 shows an energy band diagram of a solar cell in accordance with some embodiments of the present invention. In the exemplary embodiment, the solar cell may have a structure described in FIG. 1, wherein the light-absorbing layer is made of a metal, the semiconductor is a p-type semiconductor, and the main carriers are holes. The work function (qϕm) of the metal is smaller than the work function (qϕs) of the semiconductor.

As shown in FIG. 3, the metal and the semiconductor reach thermal equilibrium after contacting with each other, and ideally, the Fermi levels of the metal and the semiconductor are equal. If the main carrier holes (h⁺) in the semiconductor are needed to flow to the metal, the built-in electric field V_{bi} at the junction must be overcome. If the main carrier holes (h⁺) in the metal are needed to flow to the semiconductor, the barrier height #b at the junction must be overcome.

Many difficulties are needed to overcome in fabricating solar cells having metal-semiconductor junction. Almost all metals can absorb infrared light; however, the thickness of metal is difficult to determine. A metal with very thin thickness will penetrate a lot of the infrared light, and the absorption is only about 20%-30%. By contrast, a metal with very thin thickness will reflect a lot of the infrared light, and the absorption rate is lower than 10%. In addition, after the light-absorbing layer 10 absorbs the mid-infrared light, electrons will transit to a high energy level. Because the energy gap of the light-absorbing layer 10 is very low (e.g., the energy gap of metal is zero), the electrons fall back to a lower energy level in a very short time, usually a few picoseconds (10⁻¹² s). And hence the hot carriers are difficult to be collected as a photocurrent.

In order to quickly export the hot carriers, the thickness of the metal film should be small enough to allow the hot carriers to pass through the metal film before cooling. Experiments have found that when the metal layer is thinner, more hot carriers cross the metal-semiconductor interface; however, the absorption of the metal layer for incident light will also decrease. Second, hot carriers may recombine with electrons or holes during the transportation in the metal film, resulting in a sharp drop of the generated photocurrent.

In some embodiments, the Schottky barrier generated by the metal-semiconductor junction is used to block the hot carriers that pass through the metal layer and cross the energy barrier, thereby avoiding the loss caused by the recombination of the carriers. In some embodiments, the semiconductor is a silicon substrate, and a metal layer is evaporated on the surface of the silicon substrate to facilitate light transmission and form a Schottky barrier. Depending on the types of metal, the Schottky barrier is mostly ranged between 0.2-1.1 eV. The energy barrier of less than 1.1 eV gives the solar cell the ability to absorb near-infrared to mid-infrared light.

Hot Carrier Energy Redistribution Model

In addition, the collision of hot carriers with other carriers on the metal surface is simulated through the diffusion partial differential equation. During the collision, energy is exchanged between the carriers, and the number of carriers with different energies changes over time. Considering the lifetime of hot carriers, a term τ referring to the lifetime is added to modify the equation as (1):

$$\frac{\partial n}{\partial t} = - \frac{n}{τ} + C \frac{{\partial }^{2} n}{\partial {E}^{2}} ,$$

where n denotes the number of carriers, C denotes the energy exchange coefficient, E denotes energy (eV), and t denotes time.

In equation (1), an incident light condition is set, with reference to the ideal black body radiation spectrum at the same temperature as the initial carrier energy distribution, as well as to integral the spectrum before the cut-off wavelength as the initial number of carriers, and then the number of carriers with different energies varying with time can be calculated through the numerical simulation. The lifetimes and energy diffusion coefficients of various metal hot carriers measured by other laboratories (Brown, Ana M., et al. “Ab initio phonon coupling and optical response of hot electrons in plasmonic metals.” Physical Review B 94.7 (2016): 075120) are substituted into the energy diffusion equation to obtain the variation of the number of carriers with time for different metals under the same incident light condition.

Hot Carrier Spatial Diffusion Model

Next, the diffusion of hot carriers from the metal surface (with the highest carrier concentration) to the metal-silicon junction (with the lowest carrier concentration) over time is simulated. In the spatial diffusion partial differential equation, a term r referring to the lifetime of hot carriers is added to as equation (2):

$$\frac{\partial n}{\partial t} = - \frac{n}{τ} + D \frac{{\partial }^{2} n}{\partial {x}^{2}} ,$$

where n denotes the number of carriers, D denotes the thermal carrier diffusion coefficient, x denotes the distance, and t denotes the time.

In equation (2), the number of carriers corresponding to the same incident light condition is used as the initial value to calculate the diffusion of high-energy carriers inside the metal thin film. By substituting the respective carrier lifetime and spatial diffusion coefficient of varied metals, the spatial diffusion of hot carriers for each metal can be obtained. In this way, the number of hot carriers reaching the metal-silicon junction for different metals under different film thicknesses is estimated through the modeling, and the optimal thickness of the metal layer is determined based on the modeling result and the absorption of incident light for metal layers with different thicknesses.

Table 2 lists the calculated hot carrier lifetime and diffusion length of varied metals according to equations (1) and (2).

TABLE 2

| | | | Lifetime | |
|---|---|---|---|---|
| | Schottky | Cut-off | of hot | Diffusion |
| | barrier | wavelength | carriers | length of hot |
| Metal | (eV) | (μm) | (fs) | carriers (nm) |
| Ag | 0.21 | 5.904 | 57 | 34 |
| Cr | 0.45 | 2.756 | 50 | 29 |
| Cu | 0.6 | 2.067 | 37 | 27 |
| Au | 1.05 | 1.181 | 42 | 26 |

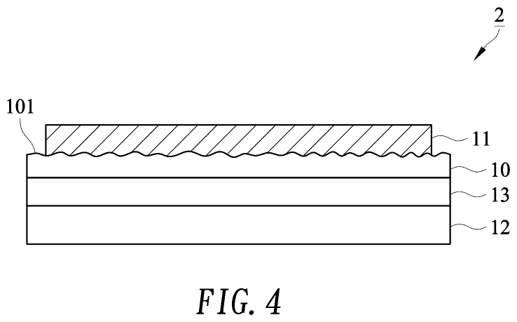

Experiments have found that when a light-absorbing layer such as a metal film is deposited by thermal evaporation, the deposition rate has an impact on the crystal morphology and characteristics of the light-absorbing layer. FIG. 4 is a schematic side view showing a solar cell 2 according to another embodiment of the present invention. The solar cell 2 is similar to the solar cell 1 described in FIG. 1, except as described below. During the fabrication of the solar cell 2, the deposition rate is controlled so that the light-absorbing layer 10 has an irregular rough surface 101.

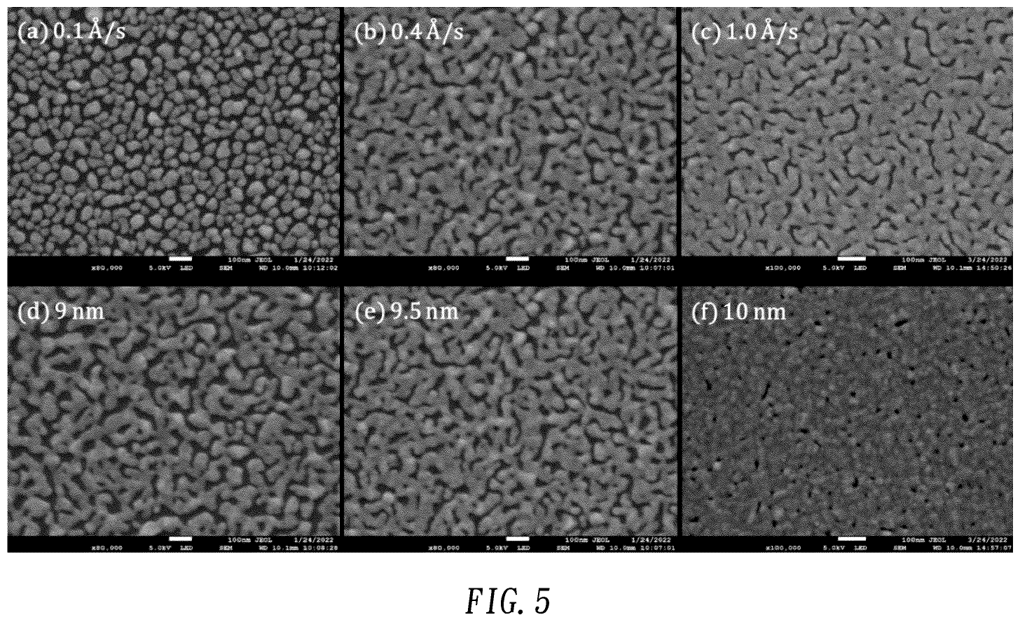

FIG. 5 is a scanning electron microscope (SEM) photograph showing the surfaces of metal films with different thicknesses deposited at different deposition rates. Where (a), (b), (c) shows 9.5 nm silver films deposited on silicon substrates with deposition rates of 0.1, 0.4, and 1.0 Å/s, respectively, and (d), (e), (f) respectively show Ag films with thickness of 9, 9.5, and 10 nm deposited on silicon substrates with deposition rate of 0.4 Å/s. From (a)-(c), it can be observed that the silver film deposited with a deposition rate of 0.1 Å/s appears multiple discrete island-like structures at the nanoscale. As the deposition rate increases, the distribution of silver atoms becomes more uniform, the voids between islands shrink, and the discontinuity decreases. In addition, an atomic force microscope (AFM) is used to scan the surface profile of the deposited film to calculate the Arithmetic Average Roughness (Ra, in pm) of the film. The results are listed in Table 3.

TABLE 3

| | Deposition rate | | |
|---|---|---|---|
| Film thickness | 0.1 Å/s | 0.4 Å/s | 1.0 Å/s |
| 9.0 nm | — | 661.13 pm | — |
| 9.5 nm | 821.73 pm | 524.38 pm | 451.36 pm |
| 10 nm | — | 439.74 pm | — |

As shown in Table 3, as the deposition rate increases, the surface roughness of the film decreases, and the film becomes flatter and more continuous. Increasing the deposition rate can give the metal atoms greater kinetic energy and improve the mobility of the metal atoms when they are deposited on the substrate, resulting in a more uniform film. In some embodiments, the rough surface 101 of the light-absorbing layer 10 has an arithmetic average roughness (Ra) between 300 μm and 700 μm. In some embodiments, rough surface 101 has an arithmetic average roughness (Ra) between 400 μm and 600 μm. In some embodiments, rough surface 101 has an arithmetic average roughness (Ra) between 450 μm and 550 μm.

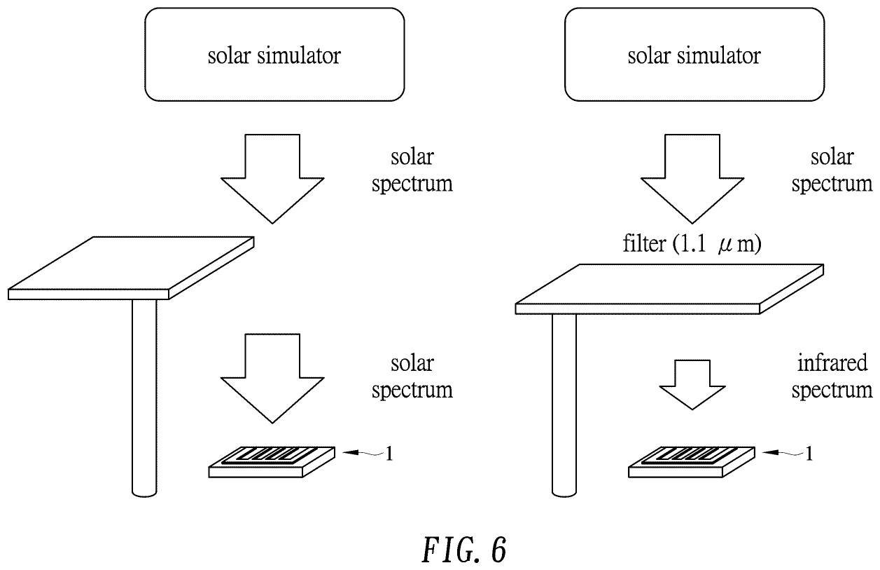

FIG. 6 shows a measuring arrangement to measure solar cell according to an embodiment of the present invention. As shown in FIG. 6, a silicon wafer with a thickness of 600 μm was used as a filter to ensure that the incident light received by the solar cell to be tested is in the wavelength range that the silicon-based solar cells cannot absorb. The sunlight generated by a solar simulator irradiates the filter, and the transmission spectrum of the filter was measured with a spectrometer. The measured transmission spectrum confirms that the sunlight with wavelengths below 1100 nm cannot transmit through the filter, and the transmittance above 1100 nm is 55%. The intensity of light transmitted through the filter was measured using an optical power meter to be 13.85 mW/cm². In addition, in order to confirm that the filter can indeed block light with wavelengths of less than 1100 nm, a commercial silicon single p-n junction solar cell was used as a comparative sample.

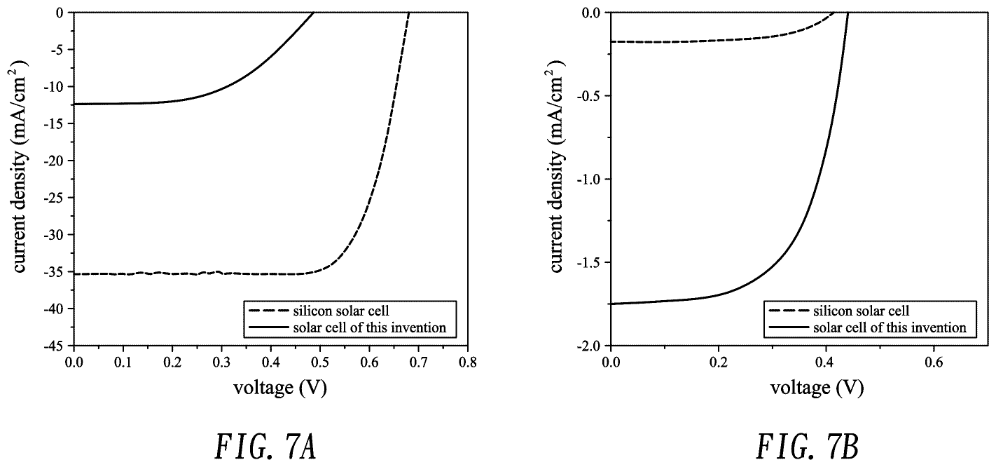

FIG. 7A and FIG. 7B show the current-voltage characteristic curves of the presented solar cell and the comparative sample, using the measuring arrangement of FIG. 6 with and without the filter, respectively. Where the semiconductor is silicon, the light-absorbing layer is silver, and the deposition rate is 0.4 Å/s. And the efficiency of the solar cell is calculated according to the following formula:

$$Cell efficiency ( \% ) = \frac{\begin{matrix}short - circuit current density \\ ( \frac{mA}{{cm}^{2}} ) \times open - circuit voltage ( v ) \times Fill fator )\end{matrix}}{{P}_{in} ( \frac{mW}{{cm}^{2}} )}$$

Wherein, Pin is the incident intensity, the short-circuit current density is the current density at zero voltage in the I-V curve, and the open-circuit voltage is the voltage at zero current in the I-V curve.

Table 4 lists the efficiencies calculated according to the I-V curves (with and without filters) of the solar cell of the present invention and the commercial silicon solar cell.

TABLE 4

| Cell efficiency | Without filter | With filter |
|---|---|---|
| Incident intensity | 100 mW/cm² | 13.85 mW/cm² |
| Commercial silicon | 17.1% | 0.176% |
| solar cell | | |
| Solar cell 2(deposition | 0.864% | 0.247% |
| rate 0.1 Å/s, | | |
| Ra = 821.73 pm) | | |
| Solar cell 2(deposition | 3.022% | 3.316% |
| rate 0.4 Å/s, | | |
| Ra = 524.38 pm) | | |

As listed in Table 4, the efficiency of the commercial silicon solar cell is 0.176% when using the filter, proving that it cannot convert light with wavelengths above 1100 nm. The efficiency of the commercial silicon solar cell without filter is 17.100, which is in line with the efficiency expectation of general silicon single p-n junction solar cells. In contrast, the solar cells provided by the present invention can effectively convert incident light with wavelengths above 1100 nm.

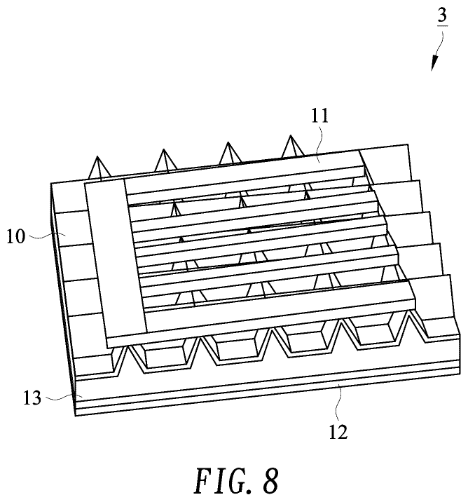

FIG. 8 is a schematic side view showing a solar cell 3 according to another embodiment of the present invention. The solar cell 3 is similar to the solar cell 1 as described in FIG. 1, except as described below.

Referring to FIG. 8, in order to enhance the absorption of infrared wavelengths, an inverted pyramid nanoarray or an inverted trapezoidal nanoarray is fabricated from the surface of the semiconductor (e.g., silicon), and the period of the nanoarray can be 4-14 μm. The pyramid or trapezoid nanoarray form cavities with multiple linear cavity lengths, a wavelength of the incident light corresponds to one of the linear cavity lengths to induce a localized surface plasmon resonance (LSPR), and different regions of the cavities induce the LSPR for different wavelengths of the incident light. Because different wavelengths can find the corresponding resonant regions in the cavities, the photoresponses from mid-infrared to the near-infrared band can be improved. According to experiments, the light-absorbing layer (e.g., metal) with a thickness of less than 20 nm can make the absorption of infrared light reach 60% or more than 80% through the inverted pyramid or trapezoidal nanoarray. In addition, in the hot carriers with energy lower than the energy barrier, the high-energy carriers give part of the energy to the low-energy carriers through collective oscillation and collision, so that the total number of carriers that can across the energy barrier increases, thereby enhancing the photocurrent.

Referring to FIG. 8, the tip structure at the bottom of the inverted pyramid causes the visible light within the range of enhancement. The short-wave light may affect the response to mid-infrared light. In order to avoid this situation, the inverted trapezoid nanoarray was fabricated by controlling the process parameters during the fabrication. The trapezoidal structure allows the enhancement to be dominated in the longer wavelength range.

The fabrication of the solar cell 3 shown in FIG. 8 is demonstrated as follows:
(a) First of all, a semiconductor substrate 13, such as a silicon substrate, is cut into a square with a side length 2.5 cm. Then, the silicon substrate was soaked in a buffered oxide etching solution (BOE) for about 10 minutes to remove the oxide layer on the surface of the substrate.
(b) Then, the silicon substrate was shaken and washed with acetone, isopropanol, and deionized water for 10 minutes, respectively.
(c) Next, a silicon dioxide film with thickness of about 600 nm is respectively deposited on the top and bottom surfaces of the silicon substrate using plasma enhanced chemical vapor deposition (PECVD). The silicon dioxide film on the top side will be used as an etching mask for anisotropic etching by potassium hydroxide solution, and the silicon dioxide film on the bottom side will be used as a protective layer during the etching.
(d) Hexamethyldisilazane (HMDS) and positive photoresist EPD-510 are spin coated on the silicon substrate, and then the silicon substrate is soft baked at 115° C. for 3 minutes to fix the photoresist on the silicon substrate.
(e) The silicon substrate is exposed and then developed with MF-319 developer to pattern the surface of the substrate.
(f) A chromium film with thickness of 30 nm is deposited on the substrate using an electron beam evaporator, and then the substrate is soaked in acetone to lift off.
(g) Reactive ion etching (RIE) is used to downward etch the silicon dioxide and the silicon substrate, and then a KOH solution is used to wet-etch the silicon substrate to complete the inverted pyramid or trapezoid nanoarray. If the inverted trapezoidal nanoarray is to be fabricated, the time of KOH-wet etching is shortened to remove the tip portion that induces resonance with the short-wave light, so that the resonance is limited to the infrared light range.
(h) The substrate is placed into a chamber of a thermal evaporation machine with a pressure less than 4×10⁻⁶ torr.
(i) Different metal films with thicknesses of 6, 8, 10, 12, and 14 nm are evaporated on the inverted pyramid or trapezoid structure at different deposition rates.
(j) A finger electrode with thickness 100 nm is evaporated on each of the metal films using a finger mask.
(k) A back electrode with thickness 100 nm is evaporated on the bottom surface of the silicon substrate to complete the metal-silicon junction solar cell.

Some embodiments further consider the effect of interface state. The metal-semiconductor junction is affected by impurities or crystal defects at the surface of the semiconductor, and charges are easily accumulated there, resulting in a decrease in photocurrent. In some embodiments, the solar cell 1, the solar cell 2, and the solar cell 3 as described in FIG. 1, FIG. 4, and FIG. 8 further include an insulating layer with an appropriate thickness between the light-absorbing layer 10 (such as metal) and the semiconductor 13, so as to reduce the impact of defects. The insulating layer may be formed by thermal oxidation. For example, through rapid thermal annealing in a high temperature and oxygen environment, a very thin silicon dioxide film is formed on the surface of the semiconductor, e.g., silicon substrate. In some embodiments, the thickness of the insulating layer is less than or equal to 10 nm. In some embodiments, the thickness of the insulating layer is less than or equal to 5 nm. In some embodiments, the thickness of the insulating layer is less than 3 nm.

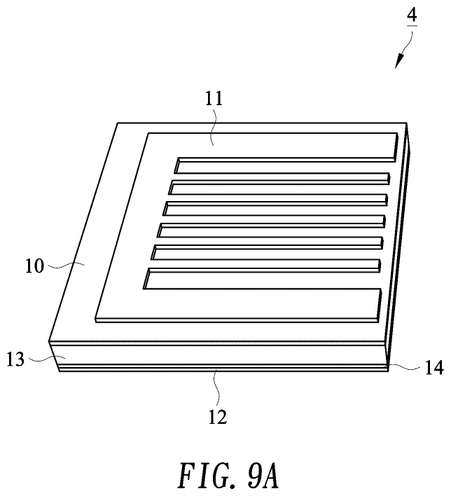

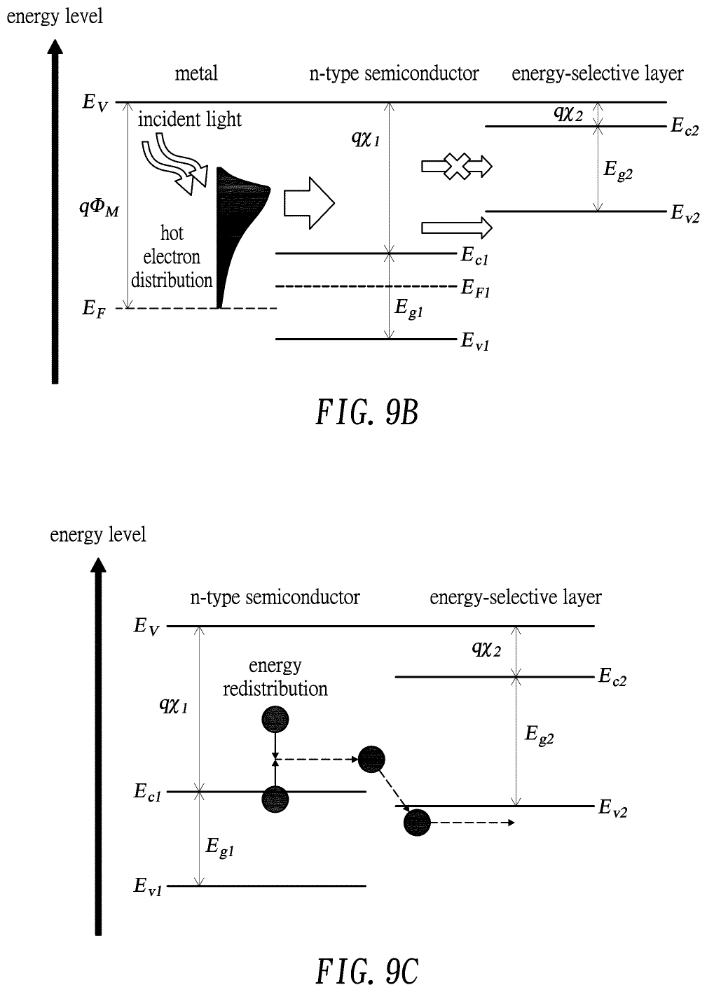

FIG. 9A is a schematic diagram showing a solar cell 4 according to another embodiment of the present invention. The solar cell 4 is similar to the solar cell 1 as described in FIG. 1, except as described below.

Referring to FIG. 9A, the solar cell 4 further includes an energy-selective layer 14 between the semiconductor 13 and the second electrode 13. The energy-selective layer 14 is typically made of a semiconductor. The energy-selective layer 14 is used as an additional energy gap to block relatively high-energy hot carriers, and through energy redistribution, the energies of carriers are close to the conduction band of the semiconductor 13, thereby increasing the number of carriers collected by the second electrode 12.

FIG. 9B shows an energy band diagram of the solar cell 4 according to one embodiment. In the exemplary embodiment, the light-absorbing layer 10 is a metal, the semiconductor 13 is an n-type semiconductor. In addition, the valence band Ev2 of the energy-selective layer 14 needs to be higher than the conduction band Ec1 of the n-type semiconductor. The energy-selective layer 14 may be made of, for example but not limited to, SiC or TiO₂.

FIG. 9C shows an energy band diagram of the solar cell 4 according to another embodiment. In this embodiment, the light-absorbing layer 10 is metal, the semiconductor 13 is an n-type semiconductor, and the valence band Ev2 of the energy-selective layer 14 is lower than the conduction band Ec1 of the n-type semiconductor. In addition, the energy difference between Ec1 and Ev2 needs to be less than 0.2 eV.

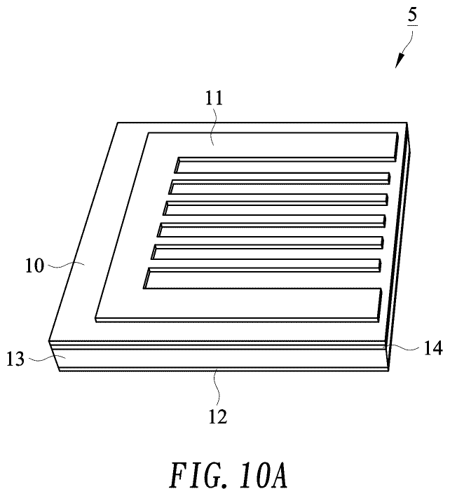

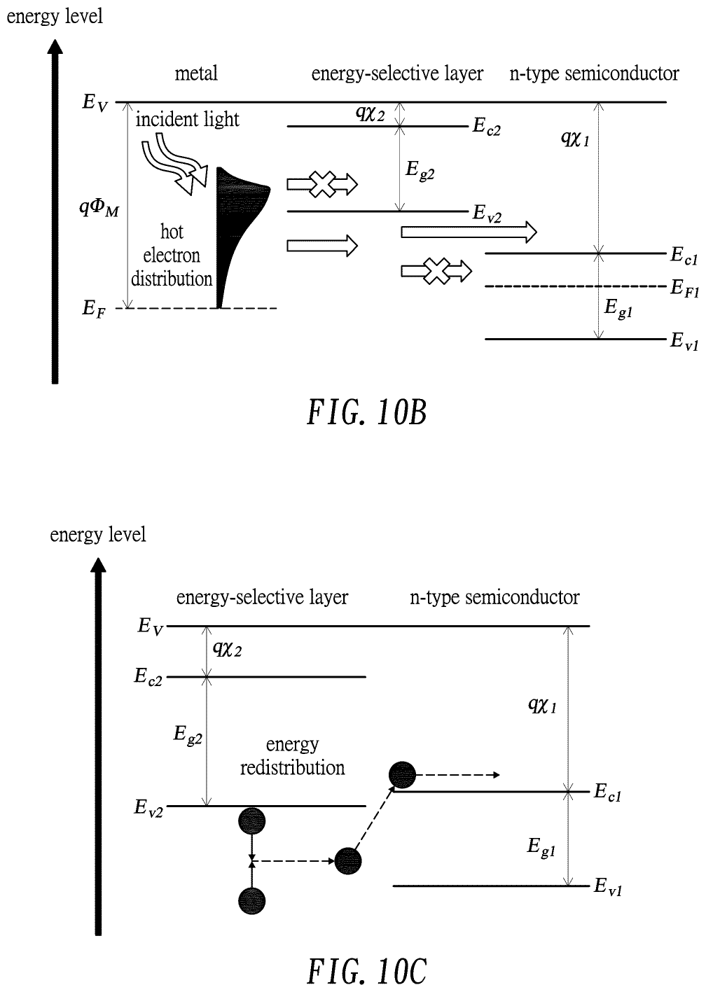

FIG. 10A is a schematic diagram showing a solar cell 5 according to another embodiment of the present invention. The solar cell 5 is similar to the solar cell 4 as described in FIG. 9A, except as described below.

Referring to FIG. 10A, in this embodiment, the energy-selective layer 14 is between the light-absorbing layer 10 and the semiconductor 13. The energy-selective layer 14 is typically made of a semiconductor. The energy-selective layer 14 is used as an additional energy gap to block relatively high-energy hot carriers, and through energy redistribution, the energies of carriers are close to the conduction band of the semiconductor 13, thereby increasing the number of carriers collected by the second electrode 12.

FIG. 10B shows an energy band diagram of the solar cell 5 according to an embodiment. In this embodiment, the light-absorbing layer 10 is a metal, the semiconductor 13 is an n-type semiconductor, and the valence band Ev2 of the energy-selective layer 14 needs to be higher than the conduction band Ec1 of the n-type semiconductor. The energy-selective layer 14 may be made of, for example but not limited to, SiC or TiO₂.

FIG. 10C shows an energy band diagram of the solar cell of FIG. 10A according to another embodiment. In this embodiment, the light-absorbing layer 10 is a metal, the semiconductor 13 is an n-type semiconductor, and the valence band Ev2 of the energy-selective layer 14 is lower than the conduction band Ec1 of the n-type semiconductor. In addition, the energy difference between Ec1 and Ev2 needs to be less than 0.2 eV.

In the embodiment of FIG. 9A, the thickness of the semiconductor 13 needs to be less than several hundreds of nanometers to prevent high-energy carriers from falling to the band edge during the migration. In the embodiment of FIG. 10A, the semiconductor 13 may be a wafer with a thickness of hundreds of micrometers.

The energy-selective layer 14 described in FIGS. 9A and 10A can also be applied to other solar cells of the present invention, e.g., the solar cells 2 or 3 as described in FIGS. 4 and 8. In the embodiment of FIG. 9A, the mentioned insulating layer may also be provided between the light-absorbing layer 10 and the semiconductor 13.

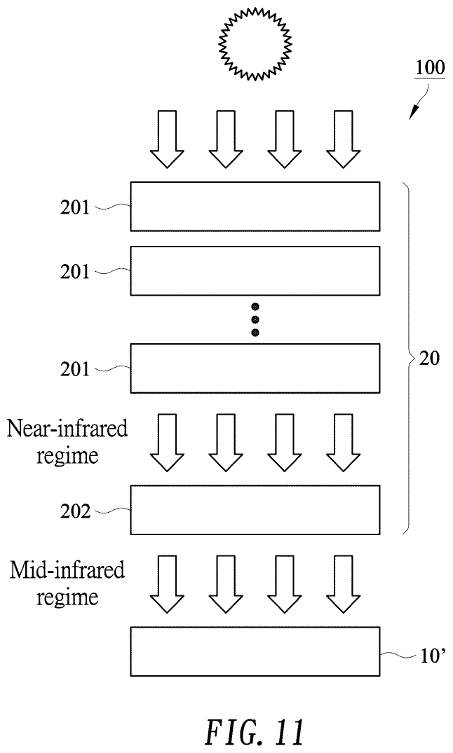

FIG. 11 is a schematic diagram illustrating a tandem solar cell 100 according to an embodiment of the present invention. Referring to FIG. 11, the tandem solar cell 100 includes a first unit 10′ and a second unit 20, wherein the first unit 10′ is mainly used to convert incident light with wavelengths greater than 1100 nm into electricity, and the second unit 20 is mainly used to convert incident light with wavelengths below 1100 nm into electricity. The first unit 10′ includes a hot carrier sub-solar cell, which may be the solar cells 1-5 previously described in FIGS. 1, 4, 8, 9A, 10A and the aforementioned insulating layer may be further provided between the light-absorbing layer 10 and the semiconductor 13. The second unit 20 includes one or more sub-solar cells, e.g., one or more perovskite sub-solar cells 201, and an optional silicon sub-solar cell 202. Each sub-solar cell may have individual positive and negative electrodes. Alternatively, all sub-solar cells share a common positive electrode and a common negative electrode. Preferably, the sub-solar cells are arranged from top to bottom according to the order of the energy gap.

In the hot carrier solar cell of the first unit 10′ according to one embodiment, the light-absorbing layer 10 is silver, the semiconductor 13 is n-type silicon, and the energy barrier is about 0.21 eV. This allows absorption of the mid-infrared light in the wavelengths below 5.9 μm, and the hot carrier solar cell can improve the efficiency of about 8.1% for the tandem solar cell 100.

The hot carrier solar cell and the tandem solar cell provided by the present invention can be produced in a lower cost and produced with a simple process. In addition, the efficiency of the tandem solar cell can be improved by the hot carrier solar cell.

Although specific embodiments have been illustrated and described, it will be appreciated by those skilled in the art that various modifications may be made without departing from the scope of the present invention, which is intended to be limited solely by the appended claims.

1. A hot carrier solar cell to convert energy of sunlight into electricity, comprising:
a semiconductor layer;
a light-absorbing layer having a lower surface in contact with an upper surface of the semiconductor layer;
a first electrode being in contact with an upper surface of the light-absorbing layer; and
a second electrode being in contact with a lower surface of the semiconductor layer;
wherein carriers in the light-absorbing layer or the semiconductor layer are excited by incident photons of sunlight to form hot carriers crossing an interface between the light-absorbing layer and the semiconductor layer and thus generating a photocurrent.

2. The hot carrier solar cell according to claim 1, wherein the energy gap of the light-absorbing layer is less than or equal to 0.5 eV.

3. The hot carrier solar cell according to claim 2, wherein the light-absorbing layer is made of metal.

4. The hot carrier solar cell according to claim 3, wherein the light-absorbing layer is made of gold, silver, copper, chromium, or nickel.

5. The hot carrier solar cell according to claim 4, wherein a Schottky barrier between 0.2-1.1 eV is formed at the interface between the light-absorbing layer and the semiconductor layer.

6. The hot carrier solar cell according to claim 2, wherein the light-absorbing layer is formed by thermal evaporation, and a deposition rate is controlled to form a rough surface on the upper surface of the light-absorbing layer.

7. The hot carrier solar cell according to claim 6, wherein the rough surface has an Arithmetic Average Roughness (Ra) between 300 μm and 700 μm.

8. The hot carrier solar cell according to claim 2, wherein the light-absorbing layer is made of semiconductor.

9. The hot carrier solar cell according to claim 8, wherein the light-absorbing layer is made of indium arsenide (InAs) or indium antimonide (InSb).

10. The hot carrier solar cell according to claim 1, wherein a thickness of the light-absorbing layer is less than 30 nm.

11. The hot carrier solar cell according to claim 1, further comprising a metal-bonding layer between the first electrode and the light-absorbing layer.

12. The hot carrier solar cell according to claim 1, further comprising a metal-bonding layer between the second electrode and the semiconductor layer.

13. The hot carrier solar cell according to claim 1, further comprising an insulating layer between the light-absorbing layer and the semiconductor layer.

14. The hot carrier solar cell according to claim 1, wherein the upper surface of the semiconductor layer includes an inverted pyramid nanoarray.

15. The hot carrier solar cell according to claim 1, wherein the upper surface of the semiconductor layer includes an inverted trapezoidal nanoarray.

16. The hot carrier solar cell according to claim 1, further comprising an energy-selective layer between the semiconductor layer and the second electrode, wherein the energy-selective layer is made of a semiconductor and the semiconductor layer is made of an n-type semiconductor.

17. The hot carrier solar cell according to claim 16, wherein the valence band of the energy-selective layer is higher than the conduction band of the n-type semiconductor.

18. The hot carrier solar cell according to claim 16, wherein the valence band of the energy-selective layer is lower than the conduction band of the n-type semiconductor, and the energy difference between the valence band of the energy-selective layer and the conduction band of the n-type semiconductor is less than 0.2 eV.

19. The hot carrier solar cell according to claim 1, further comprising an energy-selective layer between the light-absorbing layer and the semiconductor layer, wherein the energy-selective layer is made of a semiconductor and the semiconductor layer is made of an n-type semiconductor.

20. The hot carrier solar cell according to claim 19, wherein the valence band of the energy-selective layer is higher than the conduction band of the n-type semiconductor.

21. The hot carrier solar cell according to claim 19, wherein the valence band of the energy-selective layer is lower than the conduction band of the n-type semiconductor, and the energy difference between the valence band of the energy-selective layer and the conduction band of the n-type semiconductor is less than 0.2 eV.

22. A tandem solar cell, comprising
a first unit comprising a hot carrier sub-solar cell for converting incident light with wavelengths greater than 1100 nm into electricity; and
a second unit comprising one or more perovskite sub-solar cells for converting incident light with wavelengths below 1100 nm into electricity;
wherein the hot carrier sub-solar cell comprises:
a semiconductor layer;
a light-absorbing layer, a lower surface of the light-absorbing layer being in contact with an upper surface of the semiconductor layer;
a first electrode being in contact with the upper surface of the light-absorbing layer; and
a second electrode being in contact with a lower surface of the semiconductor layer;
wherein carriers in the light-absorbing layer or the semiconductor layer are excited by incident photons to form hot carriers crossing an interface between the light-absorbing layer and the semiconductor layer and thus generates a photocurrent.

23. The tandem solar cell according to claim 22, wherein the second unit further comprises a silicon sub-solar cell.

24. The tandem solar cell according to claim 22, wherein for incident light with wavelengths greater than 1100 nm and an incident intensity of 13.85 mW/cm², the conversion efficiency of the hot carrier sub-solar cell is greater than 3.3%.
